(19) United States
(12) Patent Application Publication
(10) Pub. No.: US 2025/0214148 A1
(43) Pub. Date: Jul. 3, 2025

(54) COATED TOOL AND CUTTING TOOL

(71) Applicant: KYOCERA Corporation, Kyoto (JP)

(72) Inventors: Youko KATO, Satsumasendai-shi, Kagoshima (JP); Yoshiki SAKAMOTO, Satsumasendai-shi, Kagoshima (JP)

(21) Appl. No.: 18/851,691

(22) PCT Filed: Mar. 31, 2023
(86) PCT No.: PCT/JP2023/013643

§ 371 Date: Sep. 27, 2024

(30) Foreign Application Priority Data
Mar. 31, 2022 (JP) 2022-060930

(51) Int. Cl. B23B 27/14

(52) U.S. Cl. CPC B23B 27/148; B23B 2228/105

(57) ABSTRACT

A coated tool includes a base body and a coating layer located on the base body and composed of cubic crystals. An X-ray diffraction spectrum measured for the coating layer after being held at a temperature of 1200° C. for 0.5 hours in a non-oxidizing atmosphere satisfies a relationship Ih(100)/Ih(002)≤0.9. Ih(100) is an intensity of a diffraction peak corresponding to a (100) plane of a hexagonal crystal formed in the coating layer. Ih(002) is an intensity of a diffraction peak corresponding to a (002) plane of the hexagonal crystal.

### TECHNICAL FIELD

The present disclosure relates to a coated tool and a cutting tool.

### BACKGROUND OF INVENTION

As a tool used for cutting processing such as turning processing or milling

processing, a coated tool is known in which a surface of a base body made of cemented carbide, cermet, ceramic, or the like is coated with a coating layer to improve wear resistance and the like.

### CITATION LIST

### Patent Literature

Patent Document 1: JP 2002-3284 A

### SUMMARY

A coated tool according to an aspect of the present disclosure includes a base body

and a coating layer located on the base body and composed of cubic crystals. An X-ray diffraction spectrum measured for the coating layer after being held at a temperature of 1200° C. for 0.5 hours in a non-oxidizing atmosphere satisfies a relationship Ih(100)/Ih(002)≤0.9. Ih(100) is an intensity of a diffraction peak corresponding to a (100) plane of a hexagonal crystal formed in the coating layer. Ih(002) is an intensity of a diffraction peak corresponding to a (002) plane of the hexagonal crystal.

### BRIEF DESCRIPTION OF THE DRAWINGS

FIG. 1 is a perspective view illustrating an example of a coated tool according to an embodiment.

FIG. 2 is a side sectional view illustrating an example of the coated tool according to the embodiment.

FIG. 3 is a diagram schematically illustrating an example of an X-ray diffraction spectrum measured for a coating layer according to the embodiment.

FIG. 4 is a cross-sectional view illustrating an example of a coating layer according to the embodiment.

FIG. 5 is a cross-sectional view illustrating an example of a Ta-containing multilayer structure and a Mo-containing multilayer structure that constitute the coating layer according to the embodiment.

FIG. 6 is a cross-sectional view illustrating an example of a first compound layer and a second compound layer that constitute the Ta-containing multilayer structure.

FIG. 7 is a cross-sectional view illustrating an example of a third compound layer and a fourth compound layer that constitute the Mo-containing multilayer structure.

FIG. 8 is a diagram schematically illustrating an example of a deposition system for forming a coating layer on a base body.

FIG. 9 is a front view illustrating an example of a cutting tool according to the embodiment.

FIG. 10 is a table showing manufacturing conditions for coating layers formed on base bodies.

FIG. 11 is a table showing configurations of the coating layers formed on the base bodies.

FIG. 12A is a diagram showing an X-ray diffraction spectrum measured for a coating layer of a coated tool of sample No. 1 after heat treatment.

FIG. 12B is a diagram showing an X-ray diffraction spectrum measured for a coating layer of a coated tool of sample No. 2 after heat treatment.

FIG. 12C is a diagram showing an X-ray diffraction spectrum measured for a coating layer of a coated tool of sample No. 3 after heat treatment.

FIG. 12D is a diagram showing an X-ray diffraction spectrum measured for a coating layer of a coated tool of sample No. 4 after heat treatment.

FIG. 13 is a table showing results of X-ray diffraction spectrum measurements and cutting tests on the coated tools of sample Nos. 1 to 4.

### DESCRIPTION OF EMBODIMENTS

The following is a detailed description of embodiments of a coated tool and a cutting tool according to the present disclosure (hereinafter referred to as “embodiments”) with reference to the drawings. The coated tool and the cutting tool according to the present disclosure are not limited by the embodiments. Embodiments can be appropriately combined so as not to contradict each other in terms of processing content. In the following embodiments, the same portions are denoted by the same reference signs, and redundant explanations are omitted.

In the embodiments described below, expressions such as “constant”, “orthogonal”, “perpendicular”, or “parallel” may be used, but these expressions do not necessarily have to be strictly “constant”, “orthogonal”, “perpendicular”, or “parallel”. In other words, each of the expressions described above allows deviations in, for example, manufacturing accuracy, installation accuracy, or the like.

As a tool used for cutting processing such as turning processing or milling processing, a coated tool is known in which a surface of a base body made of cemented carbide, cermet, ceramic, or the like is coated with a coating layer to improve wear resistance and the like.

The related art described above has room for further improvement in terms of extending tool life.

Therefore, it is expected that a technique that can overcome the aforementioned problem and extend the tool life will be achieved.

### Coated Tool

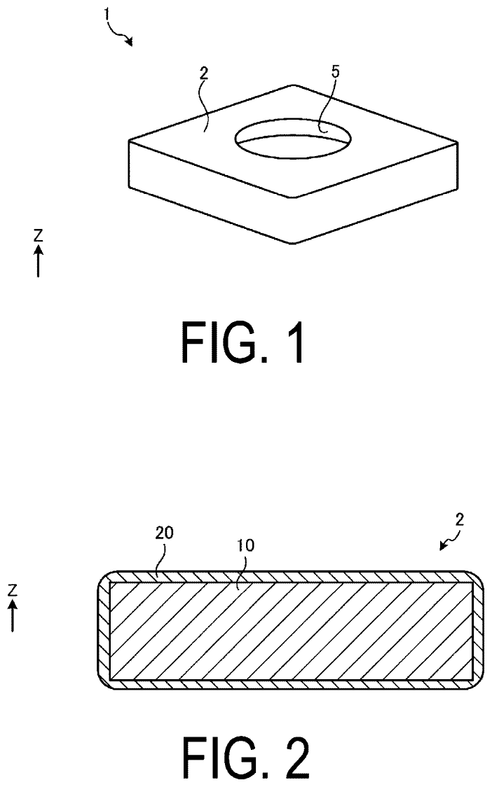

FIG. 1 is a perspective view illustrating an example of a coated tool according to an embodiment. FIG. 2 is a side sectional view illustrating an example of a coated tool 1 according to the embodiment. As illustrated in FIG. 1, the coated tool 1 according to the embodiment includes a tip body 2.

### Tip Body 2

The tip body 2 has a hexagonal shape in which a shape of an upper surface and a lower surface (surfaces intersecting a Z-axis illustrated in FIG. 1) is a parallelogram.

One corner portion of the tip body 2 functions as a cutting edge portion. The cutting edge portion has a first surface (for example, an upper surface) and a second surface (for example, a side surface) connected to the first surface. In the embodiment, the first surface functions as a “rake face” for scooping chips generated by cutting, and the second surface functions as a “flank face”. A cutting edge is located on at least a part of a ridge line where the first surface and the second surface intersect with each other, and the coated tool 1 cuts a workpiece through application of the cutting edge to the workpiece.

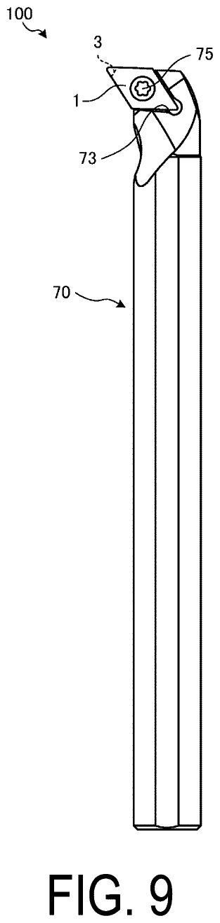

A through hole 5 that vertically penetrates the tip body 2 is located in the center portion of the tip body 2. A screw 75 for attaching the coated tool 1 to a holder 70 to be described below is inserted into the through hole 5 (see FIG. 9).

As illustrated in FIG. 2, the tip body 2 has a base body 10, and a coating layer 20.

### Base Body 10

The base body 10 is formed of, for example, cemented carbide. The cemented carbide contains tungsten (W), specifically, tungsten carbide (WC). The cemented carbide may contain nickel (Ni) or cobalt (Co). Specifically, the base body 10 is made of WC-based cemented carbide containing WC particles as a hard phase component and Co as a main component of a binding phase.

The base body 10 may be formed of a cermet. The cermet contains, for example, titanium (Ti), specifically, titanium carbide (TiC) or titanium nitride (TiN). The cermet may contain Ni or Co.

The base body 10 may be formed of a cubic boron nitride sintered body containing cubic boron nitride (cBN) particles. What the base body 10 contains is not limited to the cubic boron nitride (cBN) particles, but may be particles of, for example, hexagonal boron nitride (hBN), rhombohedral boron nitride (rBN), or wurtzite boron nitride (wBN).

The base body 10 may be formed of a ceramic. The ceramic contains, for example, aluminum oxide (Al₂O₃ oxide), such as κ-Al₂O₃ and α-Al₂O₃. The ceramic may contain other elements in the aluminum oxide. For example, the ceramic may contain, in addition to the aluminum oxide, at least one of magnesium (Mg), calcium (Ca), strontium (Sr), silicon (Si), and group 3 elements in the periodic table.

### Coating Layer 20

The base body 10 is coated with the coating layer 20 for the purpose of, for example, increasing the wear resistance and heat resistance of the base body 10. In the example in FIG. 2, the coating layer 20 entirely coats the base body 10. The coating layer 20 may be located at least on the base body 10. When the coating layer 20 is located on the first surface (here, the upper surface) of the base body 10, the first surface has high wear resistance and heat resistance. When the coating layer 20 is located on the second surface (here, the side surface) of the base body 10, the second surface has high wear resistance and heat resistance.

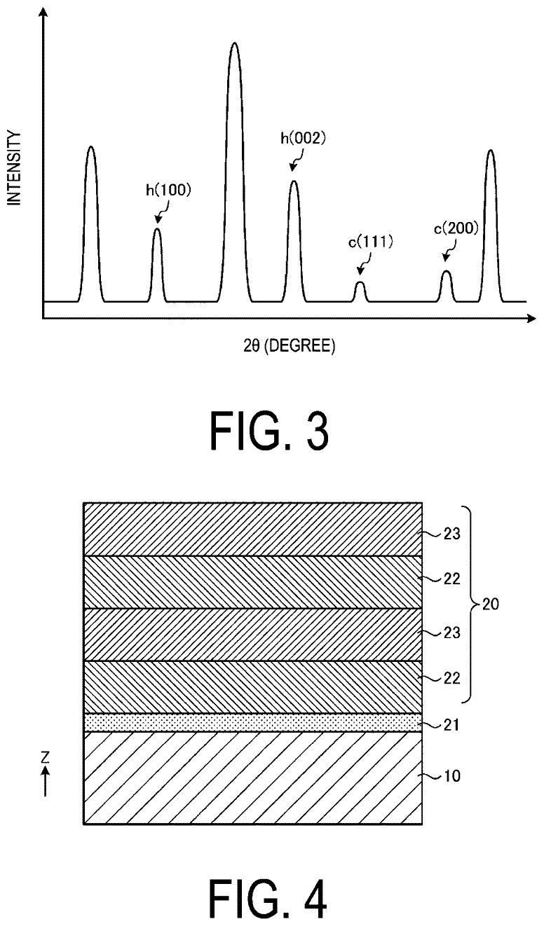

Specific characteristics of the coating layer 20 will be described with reference to FIG. 3. FIG. 3 is a diagram schematically illustrating an example of an X-ray diffraction spectrum measured for the coating layer 20 according to the embodiment. The coating layer 20 according to the embodiment is composed of cubic crystals at temperatures from room temperature to 1000° C. The coated tool 1 according to the embodiment is subjected to heat treatment in which the coating layer 20 is held at a temperature of 1200° C. for 0.5 hours in a non-oxidizing atmosphere. For example, a closed heating furnace (atmosphere furnace) can be used for the heat treatment. As the non-oxidizing atmosphere, for example, a neutral gas such as nitrogen or hydrogen, an inert gas such as helium or argon, or the like can be used.

Such heat treatment causes a phase transformation of cubic crystals that constitute the coating layer 20 according to the embodiment to hexagonal crystals. That is, the coating layer 20 after heat treatment contains not only cubic crystals but also hexagonal crystals.

An X-ray diffraction spectrum of the coating layer 20 after heat treatment is measured using an X-ray diffractometer (XRD). As illustrated in FIG. 3, the X-ray diffraction spectrum measured after heat treatment shows various diffraction peaks such as a diffraction peak corresponding to a (111) plane of a cubic crystal, a diffraction peak corresponding to a (200) plane of a cubic crystal, a diffraction peak corresponding to a (100) plane of a hexagonal crystal, and a diffraction peak corresponding to a (002) plane of a hexagonal crystal. In FIG. 3, the diffraction peak corresponding to the (111) plane of the cubic crystal, the diffraction peak corresponding to the (200) plane of the cubic crystal, the diffraction peak corresponding to the (100) plane of the hexagonal crystal, and the diffraction peak corresponding to the (002) plane of the hexagonal crystal are denoted by c(111), c(200), h(100), and h(002), respectively.

For the coating layer 20 according to the embodiment, the X-ray diffraction spectrum measured for the coating layer 20 after heat treatment satisfies a relationship Ih(100)/Ih(002)≤0.9. Where, Ih(100) is an intensity of the diffraction peak corresponding to the (100) plane of the hexagonal crystal formed in the coating layer 20, and Ih(002) is an intensity of the diffraction peak corresponding to the (002) plane of the hexagonal crystal.

When the X-ray diffraction spectrum measured for the coating layer 20 after heat treatment satisfies the relationship Ih(100)/Ih(002)≤ 0.9, among the hexagonal crystals formed in the coating layer 20, a proportion of hexagonal crystals oriented such that the (002) planes of the hexagonal crystals are parallel to the surface of the base body 10 on which the coating layer 20 is provided (the directions of the c-axes of the hexagonal crystals are perpendicular to the surface of the base body 10) (hereinafter referred to as “hexagonal crystals with a first orientation”) is greater than a proportion of hexagonal crystals oriented such that the (100) planes of the hexagonal crystals are parallel to the surface of the base body 10 (the directions of the c-axes of the hexagonal crystals are perpendicular to the surface of the base body 10) (hereinafter referred to as “hexagonal crystals with a second orientation”).

The hexagonal crystal with the first orientation easily slips on the (002) plane, and the hexagonal crystal with the second orientation easily slips on the (100) plane. The (002) plane of the hexagonal crystal is more likely to cause slippage between planes than the (100) plane of the hexagonal crystal. Therefore, when the proportion of the hexagonal crystals with the first orientation is larger than the proportion of the hexagonal crystals with the second orientation, it is considered the slippage of the (002) plane is likely to occur. As a result, it is considered damage caused by welding of a workpiece (damage such as film peeling and chipping due to falling off of a melted portion) can be minimized, and welding resistance and chipping resistance of the coating layer 20 can be improved.

When cutting the workpiece with the coated tool 1 according to the embodiment, deformation of the hexagonal crystal with the first orientation is considered to be smaller than deformation of the hexagonal crystal with the second orientation. Therefore, when the proportion of hexagonal crystals with the first orientation is greater than the proportion of hexagonal crystals with the second orientation, it is considered a decrease in hardness of the coating layer 20 can be reduced. As a result, it is considered the wear resistance of the coating layer 20 can be improved.

Thus, when the X-ray diffraction spectrum measured for the coating layer 20 after heat treatment satisfies the relationship Ih(100)/Ih(002)≤0.9, the life of the coated tool 1 can be extended.

During high-speed machining, a temperature of the coated tool 1 is around 1200° C. Accordingly, heat treatment in which the coating layer 20 is held at a temperature of 1200° C. for 0.5 hours in a non-oxidizing atmosphere is considered to correspond to high-speed machining (machining at a cutting speed of 200 m/min or less) using the coated tool 1. During high-speed machining, when the temperature of the coating layer 20 composed of the cubic crystals rises to around 1200° C., the hexagonal crystals are generated in the coating layer 20. In general, as the proportion of hexagonal crystals increases, the hardness and the wear resistance of the coating layer tend to decrease. As a result, the life of the coated tool in high-speed machining tends to be shortened. However, in the coated tool 1 according to the embodiment, the X-ray diffraction spectrum measured for the coating layer 20 after heat treatment satisfies the relationship Ih(100)/Ih(002)≤0.9, thereby reducing a decrease in the wear resistance of the coating layer 20 in high-speed machining, and improving the welding resistance and the chipping resistance of the coating layer 20 to the workpiece. On the other hand, in low-speed machining, the temperature of the coated tool 1 is

about room temperature to 1000° C. In this case, since the coating layer 20 is composed of cubic crystals, the hardness and the wear resistance of the coating layer 20 are maintained. The hardness and toughness of the coating layer 20 can be improved by the configuration of the coating layer 20 in which the X-ray diffraction spectrum measured for the coating layer 20 after heat treatment satisfies the relationship Ih(100)/Ih(002)≤0.9 as described later. As a result, the wear resistance of the coating layer 20 can be improved in low-speed machining.

Thus, when the X-ray diffraction spectrum measured for the coating layer 20 after heat treatment satisfies the relationship Ih(100)/Ih(002)≤0.9, the life of the coated tool 1 can be extended in both low-speed machining and high-speed machining.

The X-ray diffraction spectrum measured for the coating layer 20 after heat treatment may satisfy a relationship Ih(100)/Ih(002)≤0.3. In this case, the proportion of hexagonal crystals with the first orientation can be further increased. As a result, the life of the coated tool 1 can be further extended.

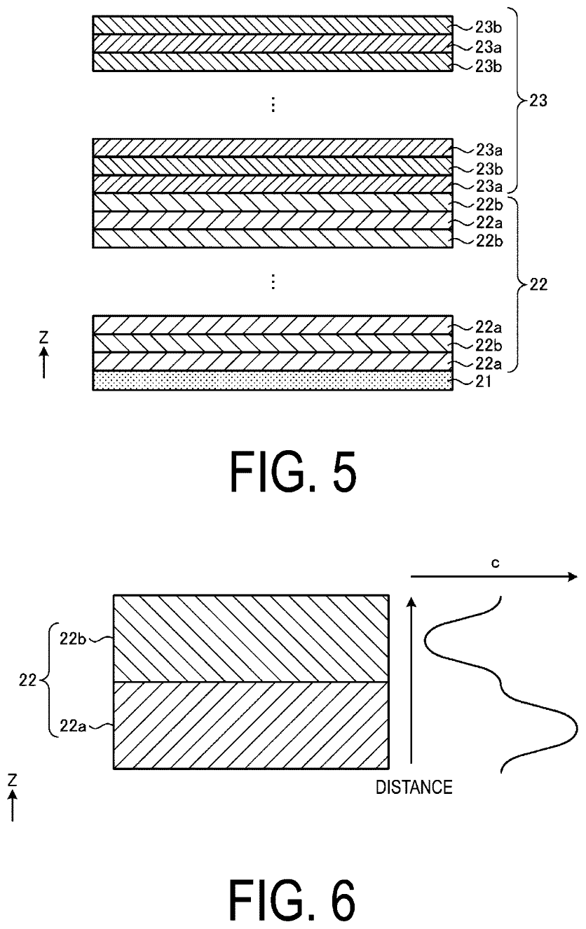

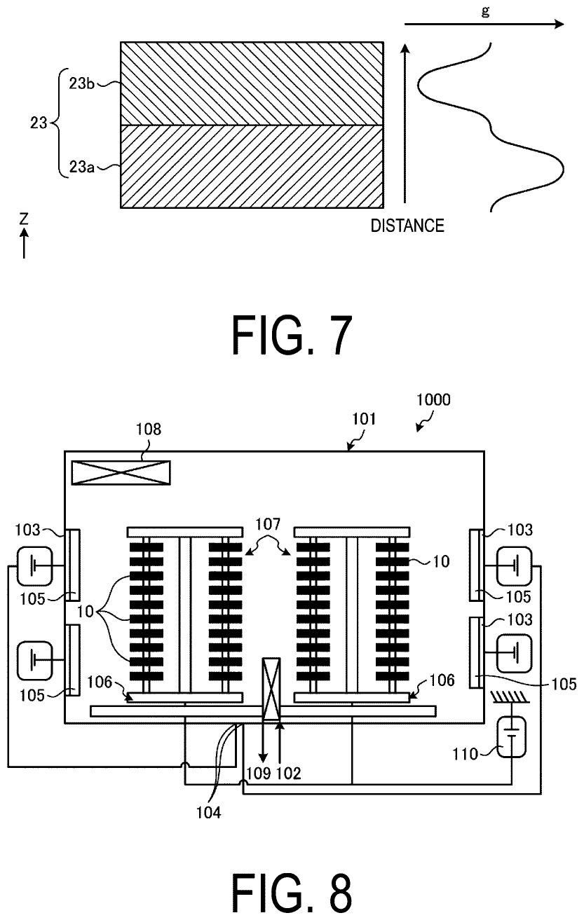

A specific configuration of the coating layer 20 in which the X-ray diffraction spectrum measured for the coating layer 20 after heat treatment satisfies the relationship Ih(100)/Ih(002)≤0.9 will be described with reference to FIGS. 4, 5, 6, and 7. FIG. 4 is a cross-sectional view illustrating an example of the coating layer 20 according to the embodiment. FIG. 5 is a cross-sectional view illustrating an example of a Ta-containing multilayer structure and a Mo-containing multilayer structure that constitute the coating layer 20 according to the embodiment. FIG. 6 is a cross-sectional view illustrating an example of a first compound layer and a second compound layer that constitute the Ta-containing multilayer structure. FIG. 7 is a cross-sectional view illustrating an example of a third compound layer and a fourth compound layer that constitute the Mo-containing multilayer structure.

As illustrated in FIG. 4, the coating layer 20 includes multiple Ta-containing multilayer structures 22 and multiple Mo-containing multilayer structures 23 located on an intermediate layer 21. Each of the plurality of Ta-containing multilayer structures 22 is a multilayer structure containing at least Ta. Each of the plurality of Mo-containing multilayer structures 23 is a multilayer structure containing at least Mo.

As illustrated in FIG. 4, the multiple Ta-containing multilayer structures 22 and the multiple Mo-containing multilayer structures 23 may be alternately layered in the coating layer 20.

In this case, residual stress between the Ta-containing multilayer structure 22 and the Mo-containing multilayer structure 23 can be reduced. Thus, peeling or cracking between the Ta-containing multilayer structure 22 and the Mo-containing multilayer structure 23 can be reduced. Effects of the Ta-containing multilayer structure 22 and the Mo-containing multilayer structure 23 described later can be improved. As a result, the life of the coated tool 1 can be extended.

The average value of thicknesses of the plurality of Ta-containing multilayer structures 22 and the plurality of Mo-containing multilayer structures 23 may be from 300 nm to 500 nm.

In this case, residual stress between the Ta-containing multilayer structure 22 and the Mo-containing multilayer structure 23 can be reduced. Thus, peeling or cracking between the Ta-containing multilayer structure 22 and the Mo-containing multilayer structure 23 can be reduced. Effects of the Ta-containing multilayer structure 22 and the Mo-containing multilayer structure 23 described later can be improved. As a result, the life of the coated tool 1 can be extended.

### Intermediate Layer 21

The intermediate layer 21 may be located between the base body 10 and the coating layer 20. Specifically, the intermediate layer 21 has one surface (here, a lower surface) in contact with the upper surface of the base body 10 and the other surface (here, an upper surface) in contact with a lower surface of the coating layer 20 (for example, the Ta-containing multilayer structure 22).

The intermediate layer 21 has higher adhesion to the base body 10 than the coating layer 20. Examples of metal elements having such characteristics include Zr, Hf, V, Nb, Ta, Cr, Mo, W, Al, Si, Y, and Ti. The intermediate layer 21 contains at least one metal element among the above metal elements. For example, the intermediate layer 21 may contain Ti. Si is a metalloid element, but in the present specification, it is assumed that metalloid elements are also included in metal elements.

When the intermediate layer 21 contains Ti, a content percentage of Ti in the intermediate layer 21 may be 1.5 atomic % or more. For example, the content percentage of Ti in the intermediate layer 21 may be 2.0 atomic % or more.

The intermediate layer 21 may contain components other than the above-described metal elements (Zr, Hf, V, Nb, Ta, Cr, Mo, W, Al, Si, Y, and Ti). However, in terms of adhesion to the base body 10, the intermediate layer 21 may contain at least 95 atomic % or more of the above metal elements in a combined amount. The intermediate layer 21 may contain 98 atomic % or more of the above metal elements in a combined amount. The ratio of the metal components in the intermediate layer 21 can be identified by, for example, analysis using an energy dispersive X-ray spectrometer (EDS) attached to a scanning transmission electron microscope (STEM).

Thus, by providing the intermediate layer 21 having higher wettability with the base body 10 than the coating layer 20 between the base body 10 and the coating layer 20, the adhesion between the base body 10 and the coating layer 20 can be improved. Since the intermediate layer 21 also has high adhesion to the coating layer 20, the coating layer 20 is less likely to peel off from the intermediate layer 21.

The thickness of the intermediate layer 21 may be, for example, 0.1 nm or greater and less than 20 nm.

### Ta-Containing Multilayer Structure 22

As illustrated in FIG. 5, each of the multiple Ta-containing multilayer structures 22 includes a first compound layer 22a and a second compound layer 22b. The first compound layer 22a contains Ta at a first composition ratio. The second compound layer 22b contains Ta at a second composition ratio different from the first composition ratio. Note that one of the first composition ratio and the second composition ratio may be 0.

Thus, each of the plurality of Ta-containing multilayer structures 22 includes the first

compound layer 22a containing Ta at the first composition ratio and the second compound layer 22b containing Ta at the second composition ratio different from the first composition ratio, which improves thermal shock resistance, oxidation resistance, and hardness at high temperatures of the coating layer 20. As a result, the life of the coated tool 1 can be extended.

The first compound layer 22a and the second compound layer 22b may each contain Al, Ti, and Ta. In this case, Al(1), which is a content percentage of Al contained in the first compound layer 22a, Ti(1), which is a content percentage of Ti contained in the first compound layer 22a, Ta(1), which is a content percentage of Ta contained in the first compound layer 22a, Al(2), which is a content percentage of Al contained in the second compound layer 22b, Ti(2), which is a content percentage of Ti contained in the second compound layer 22b, and Ta(2), which is a content percentage of Ta contained in the second compound layer 22b, may have relationships of Al(1)<Al(2), Ti(1)<Ti(2), and Ta(1)>Ta(2). Ta(2) may be 0.

When Al(1), Ti(1), Ta(1), Al(2), Ti(2), and Ta(2) have the relationships of Al(1)<Al(2), Ti(1)<Ti(2), and Ta(1)>Ta(2), residual stress between the first compound layer 22a and the second compound layer 22b can be reduced, and hardness and adhesion of the first compound layer 22a and the second compound layer 22b can be maintained. Thus, peeling or cracking between the first compound layer 22a and the second compound layer 22b can be reduced, and the strength of the coating layer 20 can be improved. As a result, the life of the coated tool 1 can be extended.

The first compound layer 22a and the second compound layer 22b may each contain a Ta-containing compound represented by formula (1):

(AlₐTi_{b}Ta_{c})N (1)

where, a, b, and c satisfy relationships 0.35≤a≤0.65, 0.3≤b≤0.5, 0.02≤c≤0.2, and a+b+c=1.

When a satisfies the relationship of 0.35≤a≤0.65, the hardness and the wear resistance of the coating layer 20 can be maintained. When b and c satisfy the relationships 0.3≤b≤0.5 and 0.02≤c≤0.2, the oxidation resistance of the coating layer 20 can be maintained and the strength of the coating layer 20 at high temperatures can be improved. As a result, the life of the coated tool 1 can be extended.

As illustrated in FIG. 6, c for the Ta-containing compound contained in the first compound layer 22a may vary continuously in a thickness direction of the first compound layer 22a. c for the Ta-containing compound contained in the second compound layer 22b may vary continuously in a thickness direction of the second compound layer 22b. For example, as illustrated in FIG. 6, c for the Ta-containing compound contained in the first compound layer 22a may be maximum in the vicinity of the center of a distance in the thickness direction of the first compound layer 22a. c for the Ta-containing compound contained in the second compound layer 22b may be minimum in the vicinity of the center of a distance in the thickness direction of the second compound layer 22b.

In this case, the residual stress between the first compound layer 22a and the second compound layer 22b can be further reduced. Thus, peeling or cracking between the first compound layer 22a and the second compound layer 22b can be reduced. As a result, the life of the coated tool 1 can be extended.

### Mo-Containing Multilayer Structure 23

As illustrated in FIG. 5, each of the multiple Mo-containing multilayer structures 23 includes a third compound layer 23a and a fourth compound layer 23b. The third compound layer 23a contains Mo at a third composition ratio. The fourth compound layer 23b contains Mo at a fourth composition ratio different from the third composition ratio. One of the third composition ratio and the fourth composition ratio may be 0.

Thus, each of the plurality of Mo-containing multilayer structures 23 includes the third compound layer 23a containing Mo at the third composition ratio and the fourth compound layer 23b containing Mo at the fourth composition ratio different from the third composition ratio, which improves the toughness and strength of the coating layer 20. The lubricity of the coating layer 20 can be maintained even at high temperatures. As a result, the life of the coated tool 1 can be extended.

The third compound layer 23a and the fourth compound layer 23b may each contain Al, Cr, and Mo. In this case, Al(3), which is a content percentage of Al contained in the third compound layer 23a, Cr(3), which is a content percentage of Cr contained in the third compound layer 23a, Mo(3), which is a content percentage of Mo contained in the third compound layer 23a, Al(4), which is a content percentage of Al contained in the fourth compound layer 23b, Cr(4), which is a content percentage of Cr contained in the fourth compound layer 23b, and Mo(4), which is a content percentage of Mo contained in the fourth compound layer 23b, may have relationships of Al(3)<Al(4), Cr(3)>Cr(4), and Mo(3)>Mo(4). Mo(4) may be 0.

When Al(3), Cr(3), Mo(3), Al(4), Cr(4), and Mo(4) have the relationships of Al(3)<Al(4), Cr(3)>Cr(4), and Mo(3)>Mo(4), residual stress between the third compound layer 23a and the fourth compound layer 23b can be reduced. Thus, peeling or cracking between the third compound layer 23a and the fourth compound layer 23b can be reduced. The lubricity of the coating layer 20 can be maintained even at high temperatures, and the thermal shock resistance, strength, oxidation resistance, and hardness at high temperatures of the coating layer 20 can be further improved. As a result, the life of the coated tool 1 can be extended.

The third compound layer 23a and the fourth compound layer 23b may each contain a Mo-containing compound represented by formula (2):

(Al_{d}CrₑSi_{f}Mo_{g})N (2)

where, d, e, f, and g satisfy the relationships 0.35≤d≤0.65, 0.2≤e≤0.45, 0.03≤f≤0.15, 0.02≤g≤0.2, and d+e+f+g=1.

When d satisfies the relationship of 0.35≤d≤0.65, the hardness and the wear resistance of the coating layer 20 can be maintained. When e, f, and g satisfy the relationships 0.2≤e≤0.45, 0.03≤f≤0.15, and 0.02≤g≤0.2, the lubricity of the coating layer 20 at high temperatures can be maintained, and the thermal shock resistance, strength, and oxidation resistance of the coating layer 20 can be improved. As a result, the life of the coated tool 1 can be extended.

As illustrated in FIG. 7, g for the Mo-containing compound contained in the third compound layer 23a may vary continuously in a thickness direction of the third compound layer 23a. g for the Mo-containing compound contained in the fourth compound layer 23b may vary continuously in a thickness direction of the fourth compound layer 23b. For example, as illustrated in FIG. 7, g for the Mo-containing compound contained in the third compound layer 23a may be maximum in the vicinity of the center of a distance in the thickness direction of the third compound layer 23a. g for the Mo-containing compound contained in the fourth compound layer 23b may be minimum in the vicinity of the center of a distance in the thickness direction of the fourth compound layer 23b.

In this case, the residual stress between the third compound layer 23a and the fourth compound layer 23b can be further reduced. Thus, peeling or cracking between the third compound layer 23a and the fourth compound layer 23b can be reduced. As a result, the life of the coated tool 1 can be extended.

The average value of thicknesses of the first compound layer 22a, the second compound layer 22b, the third compound layer 23a, and the fourth compound layer 23b may be from 3 nm to 15 nm.

In this case, the Ta-containing multilayer structure 22 including the first compound layer 22a and the second compound layer 22b is a multilayer structure of a plurality of layers having nanoscale thicknesses. The Mo-containing multilayer structure 23 including the third compound layer 23a and the fourth compound layer 23b is a multilayer structure of a plurality of layers having nanoscale thicknesses. This can improve the strength of the coating layer 20 against external forces. This also can improve the oxidation resistance and hardness at high temperatures of the coating layer 20. As a result, the life of the coated tool 1 can be extended.

### Method of Manufacturing Coated Tool

With reference to FIG. 8, an example of a method of manufacturing the coated tool 1 according to the embodiment will be described. FIG. 8 is a diagram schematically illustrating an example of a deposition system for forming a coating layer on a base body. Note that the method of manufacturing the coated tool 1 is not limited to the method described below.

First, the base body 10 having a shape of the coated tool 1 is produced using a known method. Subsequently, the coating layer 20 is formed on the surface of the base body 10. For example, physical vapor deposition (PVD), such as ion plating or sputtering, can be used to deposit the coating layer 20. As an example, when forming the coating layer 20 by ion plating, for example, an arc ion plating deposition system (hereinafter referred to as an AIP system) 1000 as illustrated in FIG. 8 can be used.

In the AIP system 1000 illustrated in FIG. 8, a gas such as N₂ or Ar is taken into a vacuum chamber 101 from a gas inlet 102, and a high voltage is applied between a cathode electrode 103 and an anode electrode 104 located in the AIP system 1000 to generate gas plasma. Such plasma evaporates and ionizes a desired metal or ceramic from a target 105 to produce metal or ceramic ions in a high energy state. By adhering the ionized metal or ceramic to the surface of the base body 10 as a sample, the surface of the base body 10 is coated with the coating layer 20.

As illustrated in FIG. 8, a tower 107 on which multiple base bodies 10 are set may be placed on a sample support 106. A plurality of sample supports 106 (two sets in the figure) may be placed on a table (not illustrated). As illustrated in FIG. 8, a heater 108 for heating the base bodies 10, a gas discharge port 109 for discharging gas out of the system, and a bias power supply 110 for applying a bias voltage to the base bodies 10 are provided.

As the target 105, for example, a metal target independently containing metal tantalum (Ta), metal molybdenum (Mo), and one or more metals selected from group 5 elements or group 6 elements in the periodic table, Si, Y, and Ce, a composite alloy target of these metals, or a mixture target consisting of powder or sintered bodies of carbides, nitrides, or borides of these metals can be used.

A metal source is evaporated by arc discharge or glow discharge using the target 105 to ionize the metal of the metal source and simultaneously react with nitrogen (N₂) gas of the nitrogen source, methane (CH₄)/acetylene (C₂H₂) gas of the carbon source, or oxygen (O₂) gas to deposit the coating layer 20 on the surface of the base body 10.

At this time, the sample support 106 is controlled so that a distance from a position of the target 105 to a position of the base body 10 is 160 mm or more, preferably 260 mm or more. A large number of highly linear lines of magnetic force are generated from a central portion of a surface of the target 105 toward the base body 10 so that a magnetic flux density in the vicinity of the base body 10 is 0.2 to 0.8 millitesla (mT).

Nitrogen gas as a reactive gas may be taken into the AIP system 1000 to create an atmospheric pressure of 2 to 10 Pa. The temperature of the base body 10 is maintained at 300 to 500° C. A bias voltage of from −50 to −200 V is applied to the base body 10 to generate an arc discharge of from 80 to 200 A between the target 105 (cathode electrode 103) and the anode electrode 104. Metal is deposited on the base bodies 10 while rotating and revolving the base bodies 10.

The magnetic flux density in the vicinity of the base body 10 can be controlled by controlling the magnetic field, for example, by installing an electromagnetic coil or a permanent magnet, which is a magnetic field generation source, in the vicinity of the target 105, by placing a permanent magnet inside the AIP system 1000, for example, in the central portion thereof, or by adjusting the position of the target 105 adjacent to the base body 10.

The magnetic force is calculated by measuring the magnetic flux density at the position of the base body 10 with a magnetic flux density meter. The magnetic flux density is expressed in units of millitesla (mT). The distance from the position of the target 105 to the position of the base body 10 represents a distance measured at a position where the base body 10 is closest to the target 105 and a distance where the base body 10 is farthest from the target 105.

In deposition, when a period in which the base body 10 comes closest and faces the target 105 at each position of the base body 10 as illustrated in FIG. 8 is a speed of rotation of the sample, the period of the difference in the composition between the heavy metal and the light metal in the thickness direction of the coating layer 20 can be adjusted by adjusting the speed of rotation. To be specific, the speed of rotation of the base body 10 and the sample support 106 may be adjusted so as to have a period of 2 to 20 rotations per minute (rpm).

During deposition, each of the sample supports 106 on which the base bodies 10 are placed rotates while the tower 107 rotates, and the table may be rotated such that the plurality of sample supports 106 revolve. By adjusting the timing of such revolution, the thickness of each of the compound layers constituting the Ta-containing multilayer structure 22 and the Mo-containing multilayer structure 23 can be controlled.

By applying the pulsed bias voltage, the time or distance that metal ions fly from the target 105 to the base bodies 10 can be adjusted. Thus, a difference in composition between the heavy metal component and the light metal component can also be provided during deposition.

For example, when the base body 10 is positioned so as to be close to and face the target 105, the heavy metal components from the target 105 linearly fly to the base body 10, and the heavy metals are deposited on the base body 10 more than the light metals. On the other hand, when the base body 10 is positioned so as to be away from the target 105 and not to face the target 105, a deposition amount of the heavy metal components is expected to decrease because the light metal components go around and are deposited on the base body 10. At this time, it is considered that by increasing the distance from the position of the target 105 to the position of the base body 10 and maintaining a certain degree of magnetic flux density in the vicinity of the base body 10, the light metal components are promoted to go around and the composition difference between the heavy metal components and the light metal components increases.

### Cutting Tool

A configuration of a cutting tool including the coated tool 1 described above will be described with reference to FIG. 9. FIG. 9 is a front view illustrating an example of the cutting tool according to the embodiment.

As illustrated in FIG. 9, a cutting tool 100 according to the embodiment includes the coated tool 1 and the holder 70 for fixing the coated tool 1.

The holder 70 is a rod-shaped member extending from a first end (upper end in FIG. 9) to a second end (lower end in FIG. 9). The holder 70 is made of, for example, steel or cast iron. In particular, steel with high toughness of these materials may be used.

The holder 70 includes a pocket 73 at an end portion on the first end side. The pocket 73 is a portion at which the coated tool 1 is mounted. The pocket 73 has a seating surface intersecting the rotation direction of the workpiece and a restraint side surface inclined with respect to the seating surface. The seating surface is formed with a screw hole into which the screw 75 to be described below is screwed.

The coated tool 1 is located in the pocket 73 of the holder 70 and is mounted on the holder 70 by the screw 75. That is, the screw 75 is inserted into the through hole 5 of the coated tool 1, and the tip of the screw 75 is inserted into the screw hole formed in the seating surface of the pocket 73 such that the threaded portions are screwed together. Thus, the coated tool 1 is mounted on the holder 70 such that a cutting edge portion 3 protrudes outward from the holder 70.

In the embodiment, a cutting tool used for so-called turning processing is described as an example. Examples of the turning processing include boring, external turning, and groove-forming. The cutting tool is not limited to a cutting tool used for turning processing. For example, the coated tool 1 may be used as a cutting tool used for milling processing. Examples of the cutting tools used for milling processing include milling cutters such as a plain milling cutter, a face milling cutter, a side milling cutter, and a groove milling cutter, and end mills such as a single-flute end mill, a multi-flute end mill, a tapered end mill, and a ball end mill.

### EXAMPLES

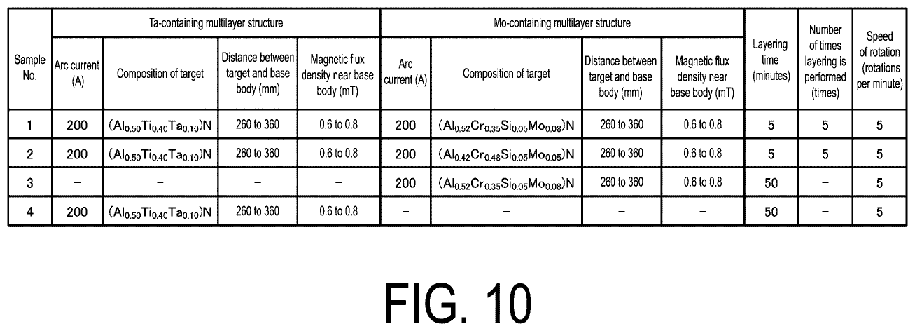

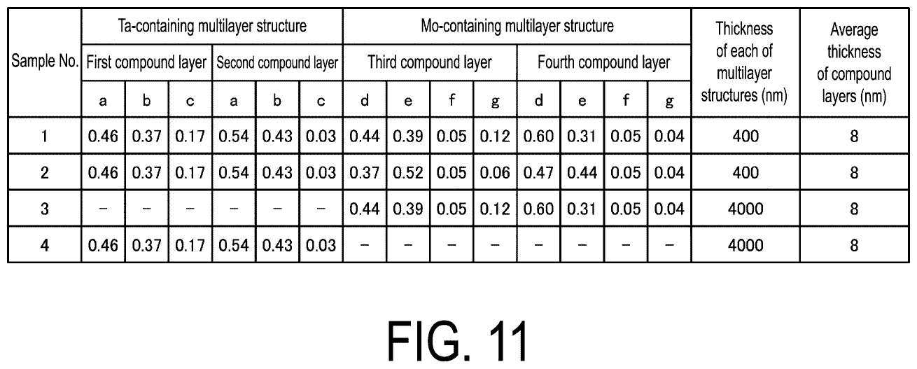

Examples of the present disclosure will be specifically described below with reference to FIGS. 10 to 13. The present disclosure is not limited to the following examples. FIG. 10 is a table showing manufacturing conditions for the coating layer formed on the base body. FIG. 11 is a table showing configurations of the coating layers formed on the base body.

Coated tools of sample Nos. 1 to 4 were produced by forming a coating layer on a base body made of a WC-based cemented carbide using the AIP system as illustrated in FIG. 8 under the manufacturing conditions shown in FIG. 10. That is, the coating layer was formed on the surface of the base body under the conditions of the arc current (mA), the composition of the target, the distance between the target and the base body (mm), the magnetic flux density in the vicinity of the base body (mT), and the speed of rotation of the sample support (rotations per minute) as shown in FIG. 10. The distance between the target and the base body (mm) was varied within a range of values shown in FIG. 10 due to rotation of the sample support. The magnetic flux density (mT) in the vicinity of the base body also varied correspondingly within a range of values shown in FIG. 10.

For the coated tools of sample Nos. 1 and 2, multiple Ta-containing multilayer structures and multiple Mo-containing multilayer structures were formed on the surface of the base body. The plurality of Ta-containing multilayer structures and the plurality of Mo-containing multilayer structures were alternately layered. For the coated tool of sample No. 3, only multiple Mo-containing multilayer structures were formed on the surface of the base body. For the coated tool of sample No. 4, only multiple Ta-containing multilayer structures were formed on the surface of the base body.

On the surface of the base body, a set of a Ta-containing multilayer structure and a Mo-containing multilayer structure, only a Ta-containing multilayer structure, or only a Mo-containing multilayer structure was formed for the number of times layering is performed (times) shown in FIG. 10. That is, each of the number of Ta-containing multilayer structures and the number of Mo-containing multilayer structures was set to be the same as the number of times layering is performed (times) shown in FIG. 10. Each of the Ta-containing multilayer structure and the Mo-containing multilayer structure was formed on the surface of the base body during the layering time (minutes) shown in FIG. 10.

As shown in FIG. 11, for the coated tools of sample Nos. 1 and 2, the Ta-containing multilayer structure was composed of the first compound layer and the second compound layer, and the Mo-containing multilayer structure was composed of the third compound layer and the fourth compound layer. For the coated tool of sample No. 3, the Mo-containing multilayer structure was composed of the third compound layer and the fourth compound layer. For the coated tool of sample No. 4, the Ta-containing multilayer structure was composed of the first compound layer and the second compound layer.

Each of the first compound layer and the second compound layer contained a Ta-containing compound represented by (AlₐTi_{b}Ta_{c}) N. Where a, b, and c were values shown in FIG. 11. The values of a, b, and c shown in FIG. 11 were average values for the Ta-containing compounds contained in the multiple first compound layers or the multiple second compound layers included in the Ta-containing multilayer structure. The average composition of the Ta-containing multilayer structures composed of the first compound layer and the second compound layer matched the composition of the target for manufacturing the Ta-containing multilayer structure shown in FIG. 10.

As shown in FIG. 11, for the coated tools of sample Nos. 1 and 2, a of the first compound layer, b of the first compound layer, c of the first compound layer, a of the second compound layer, b of the second compound layer, and c of the second compound layer had relationships a of the first compound layer<a of the second compound layer, b of the first compound layer<b of the second compound layer, and c of the first compound layer>c of the second compound layer.

Each of the third compound layer and the fourth compound layer contained a Mo-containing compound represented by (Al_{d}CrₑSi_{f}Mo_{g}). Where d, e, f, and g were values shown in FIG. 11. The values of d, e, f, and g shown in FIG. 11 were average values for the Mo-containing compounds contained in the multiple third compound layers or the multiple fourth compound layers included in the Mo-containing multilayer structure. The average composition of the Mo-containing multilayer structures composed of the third compound layer and the fourth compound layer matched the composition of the target for manufacturing the Mo-containing multilayer structure shown in FIG. 10.

As shown in FIG. 11, d of the third compound layer, e of the third compound layer, g of the third compound layer, d of the fourth compound layer, e of the fourth compound layer, and g of the fourth compound layer had relationships d of the third compound layer<d of the fourth compound layer, e of the third compound layer>e of the fourth compound layer, and g of the third compound layer>g of the fourth compound layer.

For the coated tools of sample Nos. 1 and 2, a thickness of each of the Ta-containing multilayer structure and the Mo-containing multilayer structure was 400 nm, which was the value in a field for a thickness of each multilayer structure (nm) as shown in FIG. 11. For the coated tool of sample No. 3, a thickness of the Mo-containing multilayer structure was 4000 nm as shown in FIG. 11. For the coated tool of sample No. 4, a thickness of the Ta-containing multilayer structure was 4000 nm as shown in FIG. 11.

For the coated tools of sample Nos. 1 and 2, the average thickness of the first compound layer, the second compound layer, the third compound layer, and the fourth compound layer was 8 nm, which was the value in a field for an average thickness of the compound layers (nm) as shown in FIG. 11. For the coated tool of sample No. 3, the average thickness of the third compound layer and the fourth compound layer was 8 nm as shown in FIG. 11. For the coated tool of sample No. 4, the average thickness of the first compound layer and the second compound layer was 8 nm as shown in FIG. 11.

### X-Ray Diffraction Spectrum

Each of the coated tools of sample Nos. 1 to 4 was subjected to heat treatment in which the coating layer was held at 1200° C. for 0.5 hours in a nitrogen atmosphere. Thereafter, an X-ray diffraction spectrum of the coating layer after heat treatment was measured using an X-ray diffractometer “MiniFlex600” (manufactured by Rigaku Corporation). An optical system of the above X-ray diffractometer was a focusing optical system. In the above X-ray diffractometer, Cu was used in an X-ray tube and output of the X-ray tube was 40 kV/15 mA. Measurement conditions for the X-ray diffraction spectrum were as follows.
Measurement method: 2θ scan
Measurement range: 30 degrees to 46 degrees
Step: 0.01 degrees
Scan rate: 2 degrees/minute

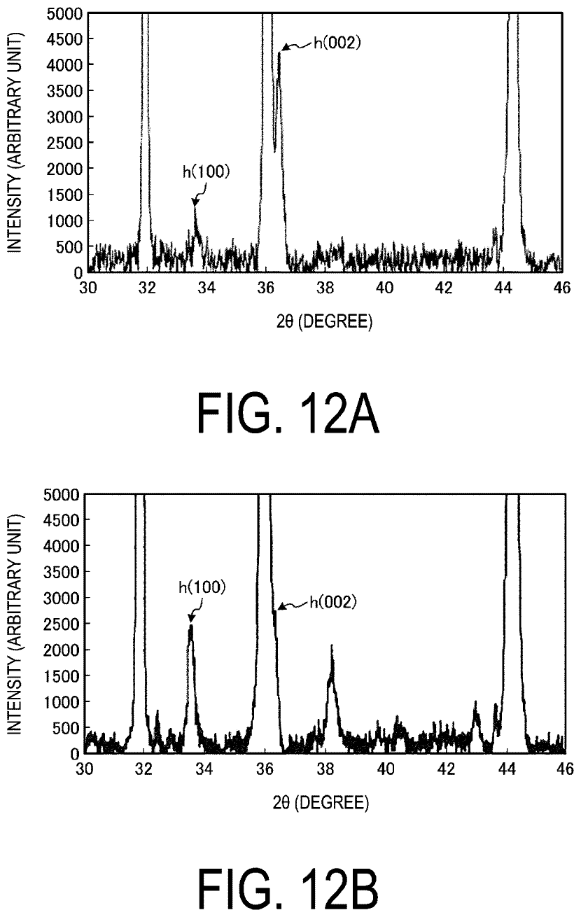

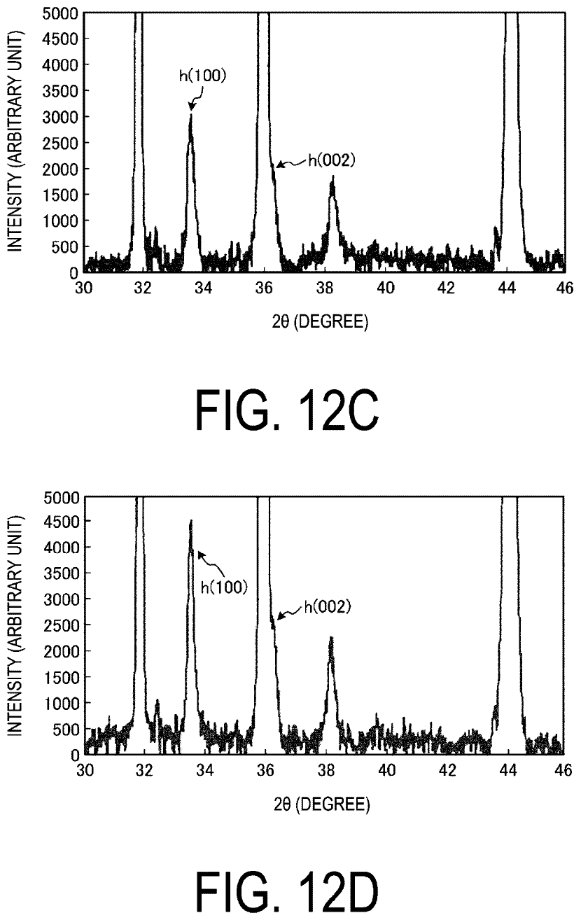

FIG. 12A is a diagram showing an X-ray diffraction spectrum measured for the coating layer of the coated tool of sample No. 1 after heat treatment. FIG. 12B is a diagram showing an X-ray diffraction spectrum measured for the coating layer of the coated tool of sample No. 2 after heat treatment. FIG. 12C is a diagram showing an X-ray diffraction spectrum measured for the coating layer of the coated tool of sample No. 3 after heat treatment. FIG. 12D is a diagram showing an X-ray diffraction spectrum measured for the coating layer of the coated tool of sample No. 4 after heat treatment.

In each of FIGS. 12A, 12B, 12C, and 12D, a horizontal axis represents the X-ray diffraction angle 2θ (degree), and a vertical axis represents the X-ray intensity (arbitrary unit). θ is the Bragg angle of the X-ray (degree).

In each of FIGS. 12A, 12B, 12C, and 12D, a diffraction peak in a range of 33 degrees to 34 degrees corresponded to the (100) plane of the hexagonal crystal of the metal nitride contained in the coating layer after heat treatment. A diffraction peak in a range of 36.3 degrees to 36.5 degrees corresponded to the (002) plane of the above hexagonal crystal.

For each of the X-ray diffraction spectra shown in FIGS. 12A, 12B, 12C, and 12D, the intensity Ih(100) of the diffraction peak corresponding to the (100) plane of the hexagonal crystal and the intensity Ih(002) of the diffraction peak corresponding to the (002) plane of the hexagonal crystal were obtained. From the obtained Ih(100) and the obtained Ih(002), their ratio Ih(100)/Ih(002) was calculated.

### Cutting Test

Cutting tests were conducted on the coated tools of sample Nos. 1 to 4. The test conditions for the cutting tests were as follows. Cutting tests were conducted under the following conditions using a carbide grade for milling (model number: PNMU1205ANER-GM) as a base body.
(1) Cutting method: Milling cutting using a square bar having a size of 80 mm×125 mm×300 mm
(2) Workpiece: FCD450
(3) Cutting speed Vc: 150 m/min and 200 m/min
(4) Feed per tooth fz: 0.12 mm/t
(5) Axial depth of cut ap: 2 mm
(6) Machining mode: Dry and wet
(7) Evaluation method: A surface of 80 mm×300 mm of the workpiece was milled under the above conditions, and the life of the coated tool was determined when the flank wear width Vb of the tool reached 0.1 mm.

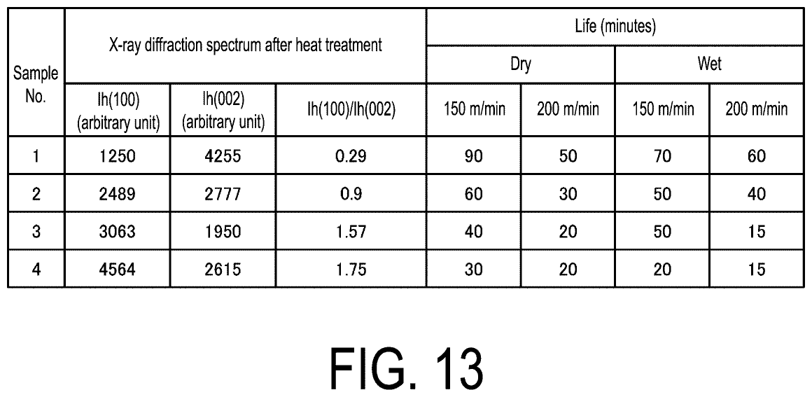

FIG. 13 is a table showing results of X-ray diffraction spectrum measurements and cutting tests on the coated tools for sample Nos. 1 to 4.

As shown in FIG. 13, for the coated tool of sample No. 1, Ih(100)/Ih(002) was 0.29.For the coated tool of sample No. 2, Ih(100)/Ih(002) was 0.9. For the coated tool of sample No. 3, Ih(100)/Ih(002) was 1.57. For the coated tool of sample No. 4, Ih(100)/Ih(002) was 1.75.

For each of the coated tools of sample Nos. 1 and 2, the X-ray diffraction spectrum measured for the coating layer after heat treatment satisfied the relationship Ih(100)/Ih(002)≤0.9. On the other hand, for each of the coated tools of sample Nos. 3 and 4, the X-ray diffraction spectrum measured for the coating layer after heat treatment did not satisfy the relationship Ih(100)/Ih(002)≤0.9. The coated tools of sample Nos. 1 and 2 correspond to the examples of the present disclosure. The coated tools of sample Nos. 3 and 4 correspond to comparative examples of the present disclosure.

Thus, it was confirmed that a coating layer was obtained in which the X-ray diffraction spectrum measured for the coating layer after being held at a temperature of 1200° C. for 0.5 hours under a non-oxidizing atmosphere satisfied the relationship Ih(100)/Ih(002)≤0.9 by forming the coating layer such that the coating layer includes multiple Ta-containing multilayer structures and multiple Mo-containing multilayer structures, each of the multiple Ta-containing multilayer structures includes the first compound layer containing Ta at the first composition ratio and the second compound layer containing Ta at the second composition ratio different from the first composition ratio, and each of the multiple Mo-containing multilayer structures includes the third compound layer containing Mo at the third composition ratio and the fourth compound layer containing Mo at the fourth composition ratio different from the third composition ratio.

As shown in FIG. 13, the lives of the coated tools of sample Nos. 1 and 2 were the same as or longer than the lives of the coated tools of sample Nos. 3 and 4 in both dry machining and wet machining, and in both low-speed machining and high-speed machining. Therefore, it was confirmed that the life of the coated tool was extended when the X-ray diffraction spectrum measured for the coating layer after being held at a temperature of 1200° C. for 0.5 hours in a non-oxidizing atmosphere satisfied the relationship Ih(100)/Ih(002)≤0.9.

Of the coated tools of sample Nos. 1 and 2, for the coated tool of sample No. 1, the X-ray diffraction spectrum measured for the coating layer after heat treatment satisfied the relationship Ih(100)/Ih(002)≤0.3. On the other hand, for the coated tool of sample No. 2, the X-ray diffraction spectrum measured for the coating layer after heat treatment did not satisfy the relationship Ih(100)/Ih(002)≤0.3.

As shown in FIG. 13, the life of the coated tool of sample No. 1 was longer than the life of the coated tool of sample No. 2 in both dry machining and wet machining, and in both low-speed machining and high-speed machining. Therefore, it was confirmed that when the X-ray diffraction spectrum measured for the coating layer after being held at a temperature of 1200° C. for 0.5 hours in a non-oxidizing atmosphere satisfied the relationship Ih(100)/Ih(002)≤0.3, the life of the coated tool was further extended.

As described above, a coated tool (as an example, the coated tool 1) according to the embodiment includes a base body (as an example, the base body 10), and a coating layer (as an example, the coating layer 20) located on the base body and composed of cubic crystals. An X-ray diffraction spectrum measured for the coating layer after being held at a temperature of 1200° C. for 0.5 hours in a non-oxidizing atmosphere satisfies a relationship Ih(100)/Ih(002)≤0.9. Ih(100) is an intensity of a diffraction peak corresponding to a (100) plane of a hexagonal crystal formed in the coating layer. Ih(002) is an intensity of a diffraction peak corresponding to a (002) plane of the above hexagonal crystal. Therefore, the coated tool according to the embodiment can extend the tool life.

The shape of the coated tool 1 illustrated in FIG. 1 is merely an example and does not limit the shape of the coated tool according to the present disclosure. The coated tool according to the present disclosure may include a body having, for example, a rotation axis and a rod-like shape extending from a first end toward a second end, a cutting edge located at the first end of the body, and a groove extending in a spiral shape from the cutting edge toward the second end of the body.

Supplementary Note (1): A coated tool includes a base body and a coating layer located on the base body and composed of cubic crystals, in which an X-ray diffraction spectrum measured for the coating layer after being held at a temperature of 1200° C. for 0.5 hours in a non-oxidizing atmosphere satisfies a relationship Ih(100)/Ih(002)≤0.9, where Ih(100) is an intensity of a diffraction peak corresponding to a (100) plane of a hexagonal crystal formed in the coating layer, and Ih(002) is an intensity of a diffraction peak corresponding to a (002) plane of the hexagonal crystal.

Supplementary Note (2): The coated tool according to Supplementary Note (1), in which the X-ray diffraction spectrum satisfies a relationship Ih(100)/Ih(002)≤0.3.

Supplementary Note (3): A cutting tool includes a holder having a rod-like shape, the holder including a pocket at an end portion of the holder, and the coated tool according to Supplementary Note (1) or (2), the coated tool being located in the pocket.

Further effects and/or variations can be easily derived by those skilled in the art. Thus, a wide variety of aspects of the present invention are not limited to the specific details and representative embodiment represented and described above. Accordingly, various changes are possible without departing from the spirit or scope of the general inventive concepts defined by the appended claims and their equivalents.

### REFERENCE SIGNS

1 Coated tool
2 Tip body
3 Cutting edge portion
5 Through hole
10 Base body
20 Coating layer
21 Intermediate layer
22 Ta-containing multilayer structure
22a First compound layer
22b Second compound layer
23 Mo-containing multilayer structure
23a Third compound layer
23b Fourth compound layer
70 Holder
73 Pocket
75 Screw
100 Cutting tool
101 Vacuum chamber
102 Gas inlet
103 Cathode electrode
104 Anode electrode
105 Target
106 Sample support
107 Tower
108 Heater
109 Gas discharge port
110 Bias power supply
1000 AIP system

1. A coated tool comprising:
a base body; and
a coating layer located on the base body and composed of cubic crystals, wherein
an X-ray diffraction spectrum measured for the coating layer after heat treatment where the coating layer is held at a temperature of 1200° C. for 0.5 hours in a non-oxidizing atmosphere satisfies a relationship Ih(100)/Ih(002)≤0.9, where
Ih(100) is an intensity of a diffraction peak corresponding to a (100) plane of a hexagonal crystal formed in the coating layer, and
Ih(002) is an intensity of a diffraction peak corresponding to a (002) plane of the hexagonal crystal.

2. The coated tool according to claim 1, wherein
the X-ray diffraction spectrum satisfies a relationship Ih(100)/Ih(002)≤0.3.

3. A cutting tool comprising:
a rod-like holder comprising a pocket at an end portion of the holder; and
the coated tool according to claim 1, the coated tool being located in the pocket.

4. The coated tool according to claim 1, wherein
the hexagonal crystal is formed by a phase transformation of the cubic crystals in the heat treatment.

5. The coated tool according to claim 1. wherein
the coating layer after the heat treatment contains the cubic crystals and the hexagonal crystal.
